(19) United States
(12) Patent Application Publication
(10) Pub. No.: US 2010/0059852 A1
(43) Pub. Date: Mar. 11, 2010

(54) SEMICONDUCTOR TRANSISTOR DEVICE WITH IMPROVED ISOLATION ARRANGEMENT, AND RELATED FABRICATION METHODS

(75) Inventors: Rohit PAL, Fishkill, NY (US); David BROWN, Pleasant Valley, NY (US); Scott LUNING, Poughkeepsie, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/209,056

(22) Filed: Sep. 11, 2008

(51) Int. Cl. H01L 29/00; H01L 21/76

(52) U.S. Cl. 257/510; 438/431; 257/E21.54; 257/E29.001

(57) ABSTRACT

A method of fabricating a semiconductor device structure is provided. The method begins by providing a substrate having a layer of semiconductor material, a pad oxide layer overlying the layer of semiconductor material, and a pad nitride layer overlying the pad oxide layer. The method proceeds by selectively removing a portion of the pad nitride layer, a portion of the pad oxide layer, and a portion of the layer of semiconductor material to form an isolation trench. Then, the isolation trench is filled with a lower layer of isolation material, a layer of etch stop material, and an upper layer of isolation material, such that the layer of etch stop material is located between the lower layer of isolation material and the upper layer of isolation material. The layer of etch stop material protects the underlying isolation material during subsequent fabrication steps.

### TECHNICAL FIELD

Embodiments of the subject matter described herein relate generally to semiconductor devices. More particularly, embodiments of the subject matter relate to the use of isolation regions between metal oxide semiconductor transistors.

### BACKGROUND

The majority of present day integrated circuits (ICs) are implemented by using a plurality of interconnected field effect transistors (FETs), which may be realized as metal oxide semiconductor field effect transistors (MOSFETs or MOS transistors). A MOS transistor may be realized as a p-type device (i.e., a PMOS transistor) or an n-type device (i.e., an NMOS transistor). Moreover, a semiconductor device can include both PMOS and NMOS transistors, and such a device is commonly referred to as a complementary MOS or CMOS device. A MOS transistor includes a gate electrode as a control electrode that is formed over a semiconductor substrate, and spaced-apart source and drain regions formed within the semiconductor substrate and between which a current can flow. The source and drain regions are typically accessed via respective conductive contacts formed on the source and drain regions. Bias voltages applied to the gate electrode, the source contact, and the drain contact control the flow of current through a channel in the semiconductor substrate between the source and drain regions beneath the gate electrode. Conductive metal interconnects (plugs) formed in an insulating layer are typically used to deliver bias voltages to the gate, source, and drain contacts.

The active semiconductor material for a MOS transistor is isolated from other regions of the surrounding semiconductor material, which may represent active regions for adjacent MOS transistors. Shallow trench isolation (STI) is commonly used to isolate the active regions for a plurality of MOS transistors formed on a substrate. STI utilizes an insulating material, such as an oxide, formed in trenches that surround the active transistor regions. STI is formed early in the fabrication process, and the transistor gate stacks can be formed such that they overlap portions of the active regions and/or portions of the STI regions.

With the introduction of new semiconductor device fabrication processes and materials (such as eSiGe, eSiC, high-k material, etc.), loss of the STI oxide is becoming problematic. STI oxide loss is caused by certain process steps, including etching and formation of silicide contacts. Increased STI oxide loss, along with shrinking device pitch, creates an unfavorable aspect ratio for gap fill processes. This can result in significant yield reductions, particularly for small process technology nodes (for example, 45 nm technology). Problems associated with the loss of STI material might worsen as process technologies continue to develop and with the integration of newer materials.

Accordingly, STI loss prevention has been a focus area for technology development. Conventional methods for addressing this problem involve the selection and/or optimization of various dry and wet etches for selectivity towards STI oxide. However, this involves significant process development and such methods may not adequately inhibit the loss of STI material. Moreover, most of the STI loss occurs during formation of silicide elements because conventional silicidation processes use significant amounts of hydrofluoric acid based (HF) wet etches.

### BRIEF SUMMARY

The techniques and technologies described herein can be utilized to reduce or eliminate the loss of STI material during the fabrication of a MOS transistor device. A MOS transistor device fabricated in accordance with the process described herein employs a buried nitride layer within the STI region, and the buried nitride region is effective at inhibiting STI oxide loss during certain process steps, such as silicidation steps.

The above and other aspects may be carried out by an embodiment of a method for fabricating a semiconductor device structure. The method begins by providing a substrate having a layer of semiconductor material, a pad oxide layer overlying the layer of semiconductor material, and a pad nitride layer overlying the pad oxide layer. The method then selectively removes a portion of the pad nitride layer, a portion of the pad oxide layer, and a portion of the layer of semiconductor material to form an isolation trench, and fills the isolation trench with a lower layer of isolation material, a layer of etch stop material, and an upper layer of isolation material. The layer of etch stop material is located between the lower layer of isolation material and the upper layer of isolation material.

A method of forming isolation regions in a semiconductor device structure is also provided. The method forms an isolation trench in a layer of semiconductor material, forms a nitride etch stop layer in the isolation trench, and covers the nitride etch stop layer with an upper insulating material. Thereafter, a transistor device structure is fabricated using an active region in the layer of semiconductor material, where the active region is adjacent to the isolation trench. This fabrication process removes at least some of the upper insulating material in the isolation trench, and leaves at least some of the nitride etch stop layer intact.

An isolation arrangement for a semiconductor device structure is also provided. The isolation arrangement includes a lower layer of insulating material, a layer of nitride material overlying the layer of insulating material, an upper region of insulating material overlying the layer of nitride material, and a gate structure formed on the upper region of insulating material.

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

### BRIEF DESCRIPTION OF THE DRAWINGS

A more complete understanding of the subject matter may be derived by referring to the detailed description and claims when considered in conjunction with the following figures, wherein like reference numbers refer to similar elements throughout the figures.

FIG. 1 is a top view of an embodiment of a semiconductor device structure having an active semiconductor region surrounded by isolation material; and

FIGS. 2-13 are cross sectional views that illustrate the fabrication of an exemplary semiconductor device structure having STI.

### DETAILED DESCRIPTION

The following detailed description is merely illustrative in nature and is not intended to limit the embodiments of the subject matter or the application and uses of such embodiments. As used herein, the word “exemplary” means “serving as an example, instance, or illustration.” Any implementation described herein as exemplary is not necessarily to be construed as preferred or advantageous over other implementations. Furthermore, there is no intention to be bound by any expressed or implied theory presented in the preceding technical field, background, brief summary or the following detailed description.

For the sake of brevity, conventional techniques related to semiconductor device fabrication may not be described in detail herein. Moreover, the various tasks and process steps described herein may be incorporated into a more comprehensive procedure or process having additional steps or functionality not described in detail herein. In particular, various steps in the manufacture of semiconductor based transistors are well known and so, in the interest of brevity, many conventional steps will only be mentioned briefly herein or will be omitted entirely without providing the well known process details.

The techniques and technologies described herein may be utilized to fabricate MOS transistor devices, including NMOS transistor devices, PMOS transistor devices, and CMOS transistor devices. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

The fabrication process described herein can be employed to manufacture semiconductor devices with improved STI structures. In preferred embodiments, the fabrication process creates a buried nitride layer in the STI trench to inhibit STI oxide loss during subsequent process steps, such as silicidation. The introduction of a nitride film in the STI arrests the erosion of the STI oxide during certain etching steps. For example, HF-based etchants are typically used to clean the active semiconductor areas before processes such as eSiGe, eSiC, high-k material deposition, and silicide. The HF-based etchants do not aggressively attack nitride and, hence, the buried nitride film acts as an etch stop for underlying STI oxide.

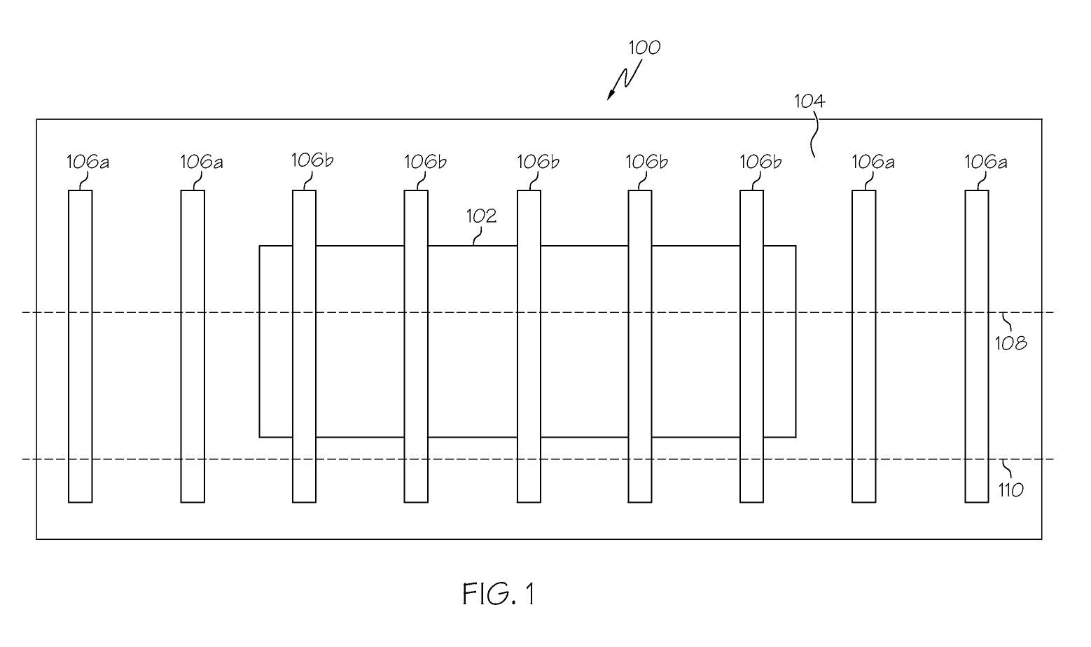

FIG. 1 is a top view of an embodiment of a semiconductor device structure 100 having an active semiconductor region 102 surrounded by isolation material, which is referred to here as STI 104. For simplicity and ease of illustration, FIG. 1 only depicts one active semiconductor region 102, however, the substrate upon which semiconductor device structure 100 is formed may include any number of additional active semiconductor regions for use with any number of transistor device structures. The illustrated embodiment includes a number of gate structures 106 formed on the substrate. Four gate structures 106a are formed over STI 104 without overlying any portion of active semiconductor region 102. These gate structures 106a may be referred to as “dummy” features because they are not actually part of working transistors. Rather, gate structures 106a can be used for loading purposes and to promote uniformity during the fabrication process. In contrast, five gate structures 106b are formed such that each one overlies a portion of STI 104 and a portion of active semiconductor region 102. These gate structures 106b can be used with working transistors that include respective source and drain regions formed in active semiconductor region 102.

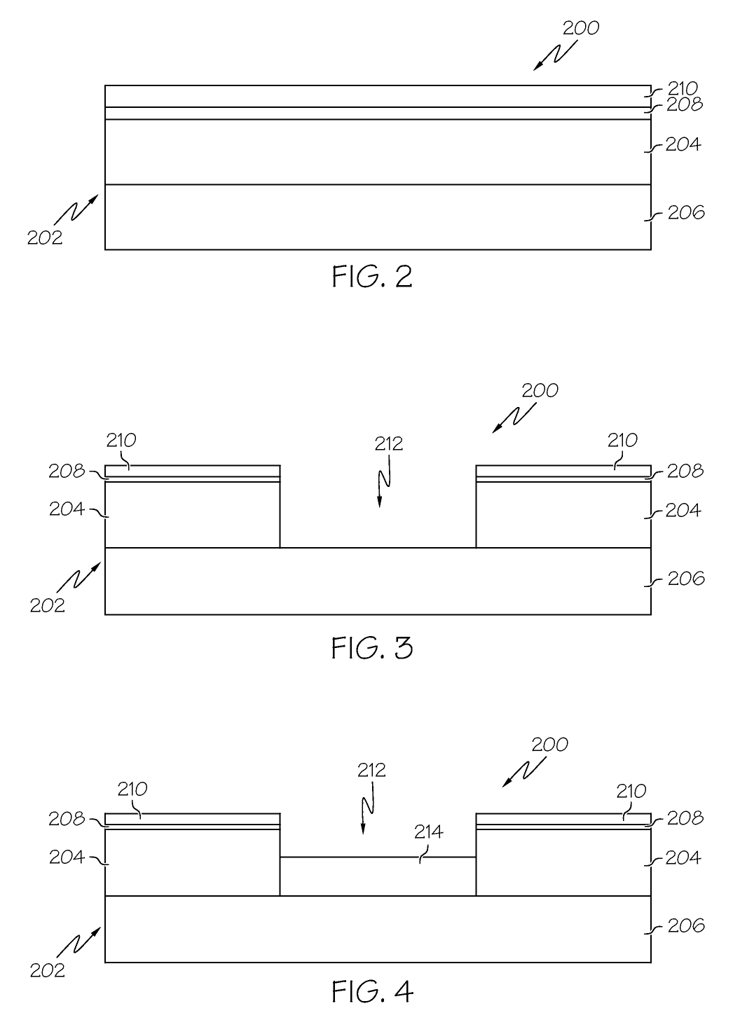

The fabrication process described here relates to the formation of an improved isolation arrangement for semiconductor devices. In this regard, FIGS. 2-13 are cross sectional views that illustrate the fabrication of an exemplary semiconductor device structure 200 having STI. This fabrication process represents one implementation of a method of forming isolation regions for use with a semiconductor device, such as a CMOS transistor device. Referring now to FIG. 2, fabrication of semiconductor device structure 200 begins by providing an appropriate semiconductor substrate 202 having a layer of semiconductor material 204. For this embodiment, semiconductor substrate 202 is realized as a silicon-on-insulator (SOI) substrate, where semiconductor material 204 is disposed on a layer of insulator material 206 that, in turn, is supported by a carrier layer (not shown). More specifically, semiconductor material 204 is a silicon material, and insulator material 206 is a buried oxide layer. The term “silicon material” is used herein to encompass the generally monocrystalline and relatively pure silicon materials typically used in the semiconductor industry. Semiconductor material 204 can originally be either N-type or P-type silicon, but is typically P-type, and semiconductor material 204 is subsequently doped in an appropriate manner to form active regions. For this embodiment, insulator material 206 is realized as a layer of silicon oxide (SiO₂). In alternate embodiments, the semiconductor device structure can be formed on a bulk silicon substrate rather than an SOI substrate.

FIG. 2 depicts semiconductor substrate 202 after formation of a pad oxide layer 208 on semiconductor material 204, and after formation of a pad nitride layer 210 on pad oxide layer 208. The resulting structure includes pad oxide layer 208 overlying semiconductor material 204, along with pad nitride layer 210 overlying pad oxide layer 208. Conventional process steps can be used to arrive at the structure depicted in FIG. 2. For example, pad oxide layer 208 is grown to the desired thickness, then pad nitride layer 210 is deposited over pad oxide layer 208 using an appropriate chemical vapor deposition (CVD) technique.

Semiconductor substrate 202 is then processed in an appropriate manner to form a suitably sized isolation trench 212 in semiconductor material 204 (FIG. 3). As depicted in FIG. 3, isolation trench 212 can be formed by selectively removing a portion of pad nitride layer 210, a portion of pad oxide layer 208, and a portion of semiconductor material 204. For this SOI implementation, isolation trench 212 is formed to at least the depth of insulator material 206 (as shown). In certain embodiments, formation of isolation trench 212 may also involve the selective removal of a portion of insulator material 206, i.e., the depth of isolation trench 212 may exceed the depth of semiconductor material 204. In a bulk semiconductor implementation, the isolation trench is formed to the desired depth within the semiconductor material itself. FIG. 3 depicts the state of semiconductor substrate 202 after completion of a number of known process steps, including photolithography, masking, and etching steps. Notably, isolation trench 212 is sized and shaped to provide sufficient isolation between the portions of semiconductor material 204 on either side of isolation trench 212.

Although other fabrication steps or sub-processes may be performed after formation of isolation trench 212, this example continues by forming a lower layer of insulation material in isolation trench 212 (FIG. 4). This insulation material is referred to herein as the lower STI material 214. In practice, lower STI material 214 partially fills isolation trench 212, and lower STI material 214 can be formed using, for example, an appropriate deposition technique such as chemical vapor deposition (CVD). In certain embodiments, lower STI material 214 is an oxide material, such as silicon dioxide deposited using tetraethyl orthosilicate (TEOS) as a silicon source (commonly referred to as TEOS oxide). As another example, silane is a very common precursor for the silicon source, and the resulting material is commonly referred to as high density plasma (HDP) oxide. As yet another example, lower STI material 214 may be an oxide formed using a high aspect ratio process (i.e., a HARP oxide).

Lower STI material 214 can be deposited to the desired thickness, which can vary depending upon the particular process technology and the specific configuration of the semiconductor device(s) being formed. For example, the thickness of lower STI material 214 can be influenced by the dimensions of the gate structures, the pitch between adjacent gate structures, applicable design rules, etc. These and possibly other parameters can be considered to arrive at a tolerable aspect ratio (related to the height and pitch of the gate structures), and that aspect ratio can be utilized to determine the desired thickness of lower STI material 214. In practice, lower STI material 214 is formed with a typical thickness of about 200-300 nm, depending upon the estimated loss of STI in the particular process flow.

Although a very thin layer of STI material may form on the inward facing sidewalls of isolation trench 212, the sidewall STI material is not shown in FIG. 4 for the sake of clarity and for ease of illustration. Moreover, FIG. 4 depicts the state of semiconductor device structure 200 after removal of any deposited STI material from the upper surfaces of pad nitride layer 210. For example, the excess STI material can be polished away using, for example, a chemical mechanical polishing (CMP) tool. In practice, pad nitride layer 210 may serve as a CMP stop layer.

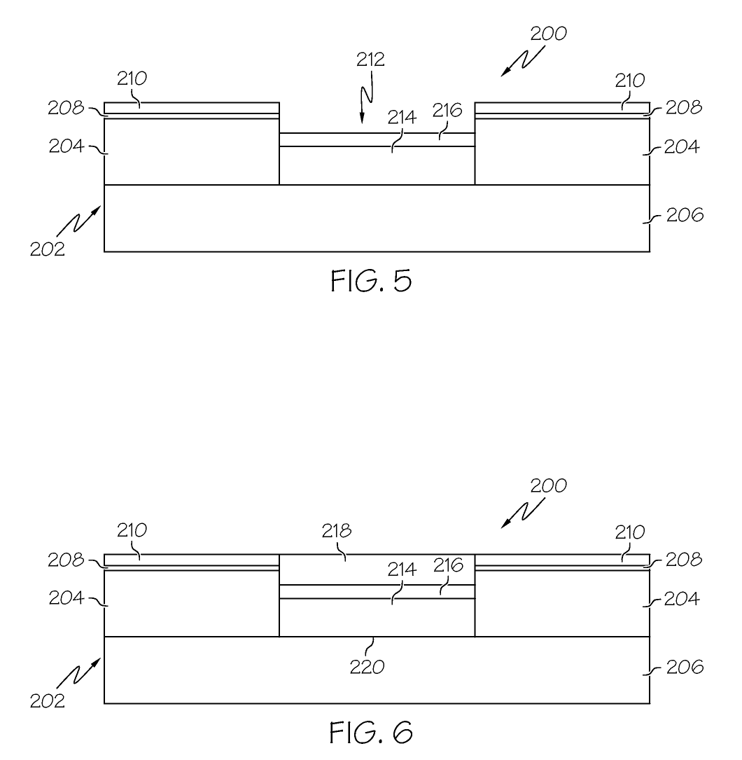

Although other fabrication steps or sub-processes may be performed after the formation of lower STI material 214, this example continues by forming a layer of etch stop material 216 in isolation trench 212 (FIG. 5). As shown in FIG. 5, this layer of etch stop material 216 is formed such that it overlies lower STI material 214. In practice, the layer of etch stop material 216 can be formed using any suitable technique, such as CVD, low pressure CVD (LPCVD), or plasma enhanced CVD (PECVD). Although preferred embodiments utilize a CVD material, etch stop material 216 could be a thermally grown material in alternate embodiments. Notably, etch stop material 216 is a material that is resistant to etchant chemistries typically utilized during silicide process modules; such etchant chemistries include, without limitation, HF-based chemistries. In preferred embodiments, etch stop material 216 is a nitride, preferably, silicon nitride.

The layer of etch stop material 216 can be deposited in isolation trench 212 and over lower STI material 214 to a desired thickness and/or height relative to the height of a reference structure or layer, such as the upper surface of semiconductor material 204. The actual thickness of etch stop material 216 will be application-specific, with a typical thickness within the range of about 1-20 nm. Although a very thin layer of etch stop material may form on the inward facing sidewalls of isolation trench 212, the sidewall material is not shown in FIG. 5. Moreover, FIG. 5 depicts the state of semiconductor device structure 200 after removal of any deposited etch stop material from the upper surfaces of pad nitride layer 210. For example, the excess etch stop material can be polished away using, for example, a CMP process.

Although other fabrication steps or sub-processes may be performed after the formation of the layer of etch stop material 216, this example continues by forming another layer of insulation material in isolation trench 212 (FIG. 6). This additional layer of insulation material is referred to herein as the upper STI material 218. In practice, upper STI material 218 is formed overlying and covering the layer of etch stop material 216 such that etch stop material 216 is located between lower STI material 214 and upper STI material 218, as depicted in FIG. 6. Preferably, the combination of lower STI material 214, etch stop material 216, and upper STI material 218 completely fills isolation trench 212, resulting in a filled trench 220.

Upper STI material 218 can be formed in the manner described above for lower STI material 214. Moreover, in preferred embodiments the composition of upper STI material 218 is the same as the composition of lower STI material 214. In other words, the same type of oxide is preferably used for both upper STI material 218 and lower STI material 214. Upper STI material 218 can be deposited such that it overfills isolation trench 212 and such that some of the deposited material overlies pad nitride layer 210 (this excess material is not shown in FIG. 6). In this regard, FIG. 6 depicts the state of semiconductor device structure 200 after removal of the excess STI material from the upper surfaces of pad nitride layer 210. For example, the excess STI material can be polished away using, for example, a CMP process with pad nitride layer 210 serving as the CMP stop layer. Although the above description assumes that intervening CMP steps are performed after formation of lower STI material 214 and after formation of etch stop material 216, an alternate embodiment may utilize a single CMP step after formation of lower STI material 214, etch stop material 216, and upper STI material 218. In other words, the excess STI and etch stop material can be polished away in one step after filling isolation trench 212 with the three layers of material.

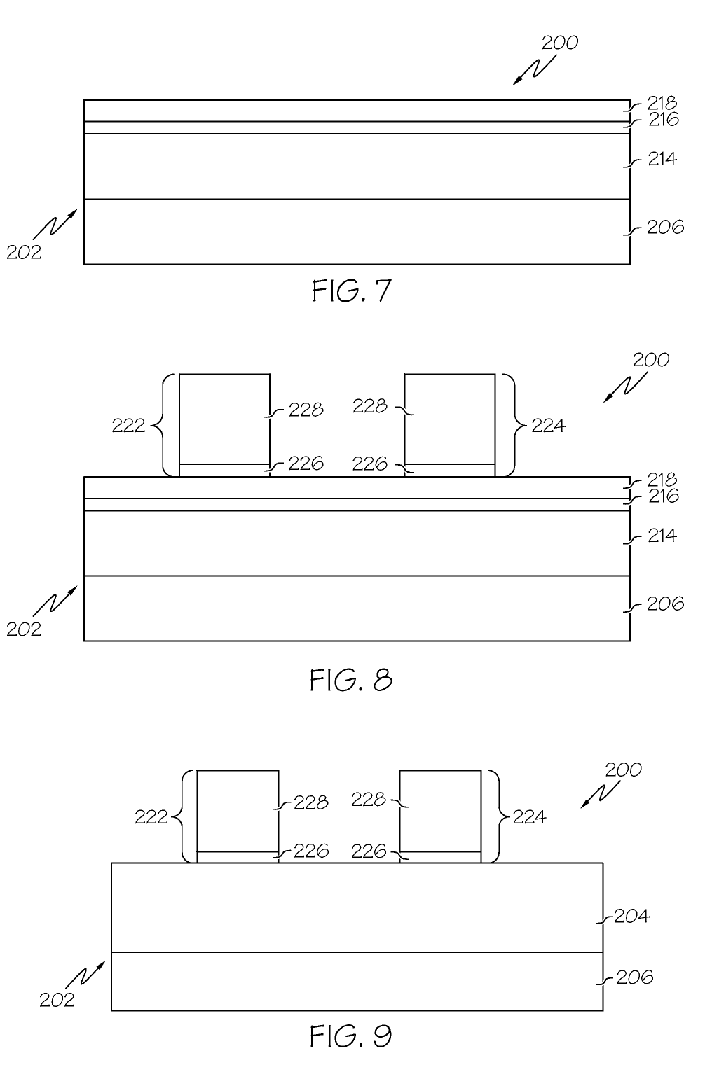

FIG. 6 depicts semiconductor device structure 200 along a cross sectional line that passes through active semiconductor regions and filled trench 220. Similarly, in FIG. 1 the cross sectional line 108 passes through active semiconductor region 102 and STI 104. In contrast, the other cross sectional line 110 in FIG. 1 passes through STI 104 but it does not pass through active semiconductor region 102. This section of semiconductor device structure 100 contains dummy gate structures 106a and nonoperational portions of gate structures 106b. These nonoperational portions can be used for contacts, interconnects, or the like. Referring now to FIG. 7, semiconductor device structure 200 is depicted as viewed from a cross sectional line that does not pass through any active semiconductor regions. Consequently, FIG. 7 depicts upper STI material 218, etch stop material 216, lower STI material 214, and insulator material 206, and FIG. 7 does not depict pad nitride layer 210, pad oxide layer 208, or any semiconductor material 204.

Although other fabrication steps or sub-processes may be performed after semiconductor device structure 200 reaches the state depicted in FIG. 7, this example continues by forming gate structures 222, 224 over filled trench 220 (FIG. 8 and FIG. 9). FIG. 8 is a cross sectional view taken along a line that does not pass through any active semiconductor regions, and FIG. 9 is a cross sectional view taken along a line that passes through active semiconductor regions, e.g., active regions formed in semiconductor material 204 (see FIG. 1). Notably, as shown in FIG. 9, gate structures 222, 224 may be formed such that they extend over an active region in the layer of semiconductor material 204. In other words, the formation of gate structures 222, 224 might be associated with the fabrication of corresponding transistor device structures on semiconductor substrate 202. Referring again to FIG. 6, this active region can be formed in the semiconductor material 204 that is adjacent to filled trench 220. Each gate structure 222, 224 may include gate insulator material 226 and gate electrode material 228 overlying gate insulator material 226. Gate structures 222, 224 can be formed using well known process steps and techniques related to material deposition, photolithography, etching, and cleaning, and the details of such steps and techniques will not be described here. In practice, some of the upper STI material 218 may be etched away during formation of gate structures 222, 224. In preferred embodiments, however, at least a portion of upper STI material 218 remains after formation of gate structures 222, 224, as depicted in FIG. 8.

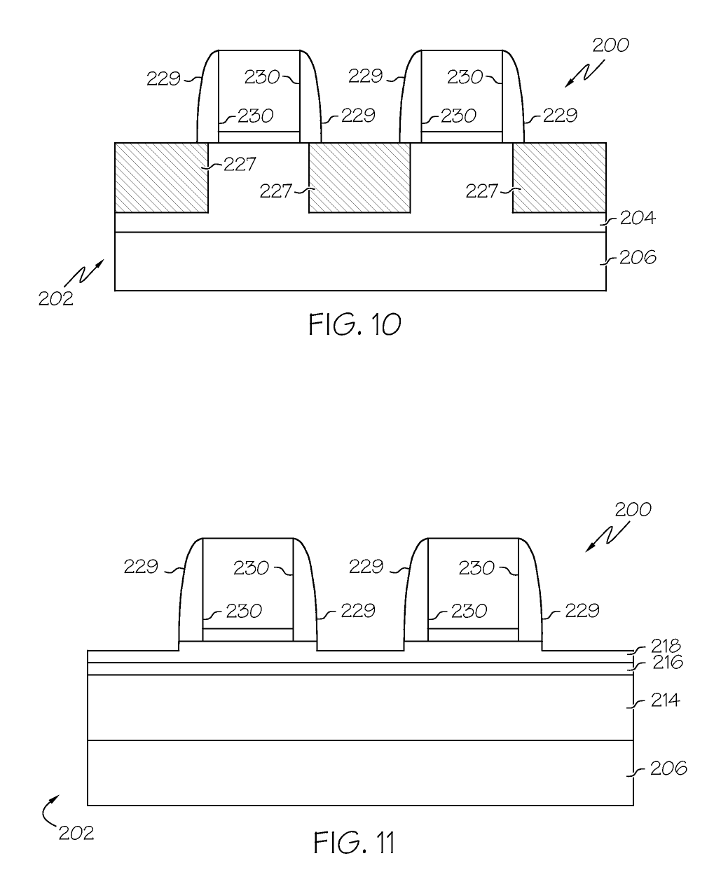

Although other fabrication steps or sub-processes may be performed after the formation of gate structures 222, 224, certain embodiments may proceed by forming stressor regions 227 in the adjacent semiconductor material 204 (FIG. 10). Stressor regions 227 are visible in FIG. 10, which is a cross sectional view taken along a line that passes through semiconductor material 204. On the other hand, these stressor regions are not visible when the device structure is viewed along a cross sectional line that does not pass through the active regions of semiconductor material 204. For an NMOS transistor device, embedded silicon carbon (eSiC) can be used to stress the channel region, and, for a PMOS transistor device, embedded silicon germanium (eSiGe) can be used to stress the channel region. These stressor regions 227 can be formed using well known process steps and techniques that will not be described in detail here. Briefly, the stressor regions 227 are formed by etching cavities in the semiconductor material 204 and thereafter filling the cavities with the stress-inducing semiconductor material (eSiC or eSiGe). Notably, the formation of stressor regions 227 may employ oxide and nitride etches.

Although other fabrication steps or sub-processes may be performed after the formation of the stressor regions 227, this example continues by creating spacers 229 about the sidewalls 230 of gate structures 222, 224 (FIG. 10 and FIG. 11). FIG. 11 is a cross sectional view taken along a line that does not pass through the active regions of semiconductor material 204. Spacers 229 can be formed using well known process steps and techniques. For example, spacers 229 are preferably formed by depositing a conformal layer of dielectric material, such as a silicon oxide, over gate structures 222, 224, and anisotropically etching the dielectric material until spacers 229 remain. Thereafter, spacers 229 and gate structures 222, 224 are used as ion implantation masks for purposes of implanting dopant ions into the semiconductor material 204, as is well understood by those familiar with semiconductor device manufacturing. Notably, the creation of spacers 229 may involve an oxide etching step, which results in the etching of some of the upper STI material 218. In preferred embodiments, at least a portion of upper STI material 218 remains after forming the stressor regions 227 and after forming spacers 229, as illustrated in FIG. 11.

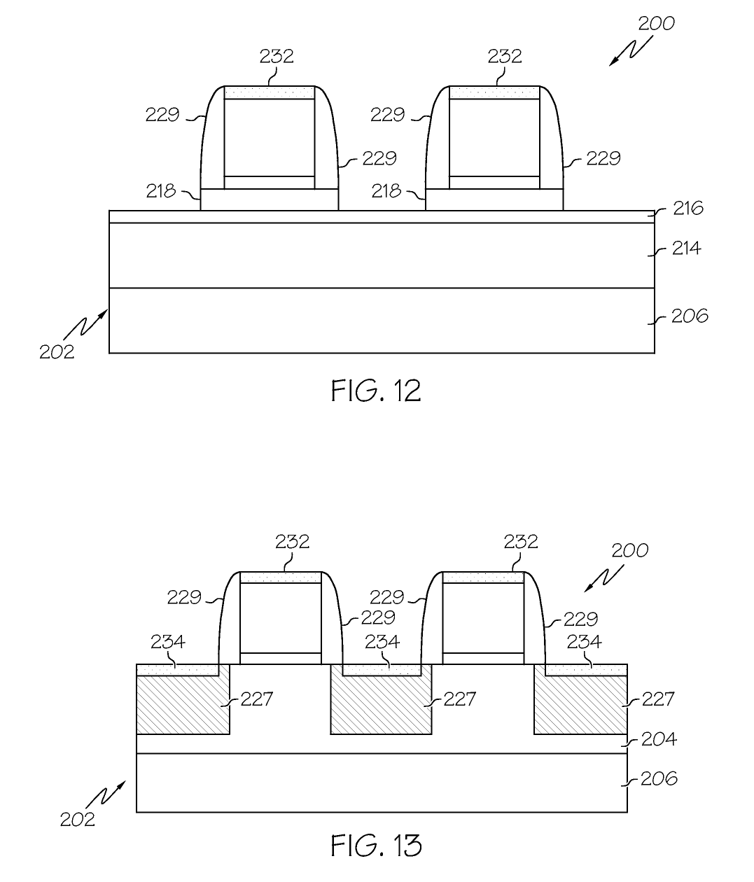

Although other fabrication steps or sub-processes may be performed after semiconductor device structure 200 reaches the state depicted in FIG. 10 and FIG. 11, this example continues by subjecting semiconductor device structure 200 to a silicidation process (FIG. 12 and FIG. 13). FIG. 12 is a cross sectional view taken along a line that does not pass through the active regions of semiconductor material 204, and FIG. 13 is a cross sectional view taken along a line that passes through the active regions of semiconductor material 204. The silicidation process results in the formation of contact areas 232 for gate structures 222, 224, and the formation of contact areas 234 for the source and drain regions of semiconductor material 204 (the source and drain contact areas 234 are shown in FIG. 13). Silicidation processes and the formation of silicide contact areas are techniques that are very common in the semiconductor manufacturing industry, and these techniques will not be described in detail here.

In practice, the silicidation process may include an oxide etching step, followed by a nitride etching step. The oxide etching step results in further etching of upper STI material 218 and, under certain conditions, this oxide etching step can completely remove the portion of upper STI material 218 that is unprotected by gate structures 222, 224 and spacers 229. This state is depicted in FIG. 12—upper STI material 218 only remains underneath gate structures 222, 224 and spacers 229. Spacers 229 formed on the sidewalls of gate structures 222, 224 define the respective boundaries of upper STI material 218. In this regard, upper STI material 218 is self-aligned with spacers 229. In other words, the outer walls of spacers 229 and the outer walls of upper STI material 218 are substantially continuous with each other, due to the etching steps utilized to create semiconductor device structure 200.

Using the fabrication steps described above, lower STI material 214 will define the STI regions that are adjacent to the active regions of semiconductor device structure 200. Notably, the layer of etch stop material 216 protects lower STI material 214 from loss during the silicidation process. That said, a portion of etch stop material 216 may be etched away during the nitride etch step of the silicidation process. In preferred embodiments, at least some of the etch stop material 216 is left intact during fabrication of the transistor device structures on semiconductor substrate 202. This state is depicted in FIG. 12—at least some of the etch stop material 216 remains over lower STI material 214, which has been fully preserved. In this way, etch stop material 216 protects underlying material in the filled isolation trench during the silicidation process. Notably, the use of etch stop layer 216 is effective at preserving the height of the STI material located between adjacent gate structures 222, 224. This is desirable for reasons related to the effectiveness of subsequent gap fill process steps.

Thereafter, any number of known process steps can be performed to complete the fabrication of the transistor devices. For the sake of brevity, these process steps and the resulting transistor devices are not shown or described here. A transistor device can be manufactured in the manner described above such that it has an isolation arrangement that does not experience undesirable losses during the fabrication process.

While at least one exemplary embodiment has been presented in the foregoing detailed description, it should be appreciated that a vast number of variations exist. It should also be appreciated that the exemplary embodiment or embodiments described herein are not intended to limit the scope, applicability, or configuration of the claimed subject matter in any way. Rather, the foregoing detailed description will provide those skilled in the art with a convenient road map for implementing the described embodiment or embodiments. It should be understood that various changes can be made in the function and arrangement of elements without departing from the scope defined by the claims, which includes known equivalents and foreseeable equivalents at the time of filing this patent application.

What is claimed is:

1. A method of fabricating a semiconductor device structure, the method comprising:
providing a substrate having a layer of semiconductor material, a pad oxide layer overlying the layer of semiconductor material, and a pad nitride layer overlying the pad oxide layer;
selectively removing a portion of the pad nitride layer, a portion of the pad oxide layer, and a portion of the layer of semiconductor material to form an isolation trench; and
filling the isolation trench with a lower layer of isolation material, a layer of etch stop material, and an upper layer of isolation material, the layer of etch stop material being located between the lower layer of isolation material and the upper layer of isolation material.

2. The method of claim 1, wherein filling the isolation trench comprises:
forming the lower layer of isolation material;
thereafter forming the layer of etch stop material overlying the lower layer of isolation material; and
thereafter forming the upper layer of isolation material overlying the layer of etch stop material.

3. The method of claim 2, wherein forming the lower layer of isolation material comprises depositing, in the isolation trench, a material selected from the group consisting of TEOS oxide, high density plasma oxide, and high aspect ratio process oxide.

4. The method of claim 2, wherein forming the layer of etch stop material comprises depositing silicon nitride in the isolation trench and over the lower layer of isolation material.

5. The method of claim 2, wherein forming the upper layer of isolation material comprises depositing, in the isolation trench, a material selected from the group consisting of TEOS oxide, high density plasma oxide, and high aspect ratio process oxide.

6. The method of claim 1, further comprising removing excess isolation material and excess etch stop material from the pad nitride layer.

7. The method of claim 1, wherein:
filling the isolation trench results in a filled trench;
the method further comprises forming a gate structure over the filled trench and over an active region in the layer of semiconductor material, the active region being adjacent to the filled trench; and
at least a portion of the upper layer of isolation material remains after forming the gate structure.

8. The method of claim 7, further comprising forming a stressor region in the active region, wherein at least a portion of the upper layer of isolation material remains after forming the stressor region.

9. The method of claim 7, further comprising creating spacers about sidewalls of the gate structure.

10. The method of claim 9, further comprising subjecting the semiconductor device structure to a silicidation process after creating the spacers, wherein the layer of etch stop material protects the lower layer of isolation material from loss during the silicidation process.

11. A method of forming isolation regions in a semiconductor device structure, the method comprising:
forming an isolation trench in a layer of semiconductor material having an active region adjacent to the isolation trench;
forming a nitride etch stop layer in the isolation trench;
covering the nitride etch stop layer with an upper insulating material; and
fabricating a transistor device structure using the active region in the layer of semiconductor material, wherein fabricating the transistor device removes at least some of the upper insulating material in the isolation trench, and leaves at least some of the nitride etch stop layer intact.

12. The method of claim 11, further comprising forming a lower layer of insulating material in the isolation trench, wherein the nitride etch stop layer is located between the lower layer of insulating material and the upper insulating material.

13. The method of claim 11, wherein covering the nitride etch stop layer comprises depositing a material selected from the group consisting of TEOS oxide, high density plasma oxide, and high aspect ratio process oxide.

14. The method of claim 11, wherein forming the nitride etch stop layer comprises depositing silicon nitride in the isolation trench.

15. The method of claim 11, wherein fabricating the transistor device structure comprises forming a gate structure overlying the upper insulating material and overlying the active region in the layer of semiconductor material, wherein at least a portion of the upper insulating material remains after forming the gate structure.

16. The method of claim 15, wherein fabricating the transistor device structure comprises creating spacers about sidewalls of the gate structure, wherein at least some of the upper insulating material remains after creating the spacers.

17. The method of claim 16, further comprising subjecting the transistor device structure to a silicidation process after creating the spacers, wherein the nitride etch stop layer protects underlying material in the isolation trench from loss during the silicidation process.

18. An isolation arrangement for a semiconductor device structure, the isolation arrangement comprising:
a lower layer of insulating material;
a layer of nitride material overlying the lower layer of insulating material;
an upper region of insulating material overlying the layer of nitride material; and
a gate structure formed on the upper region of insulating material.

19. The isolation arrangement of claim 18, further comprising spacers formed on sidewalls of the gate structure, wherein the upper region of insulating material is self-aligned with the spacers.

20. The isolation arrangement of claim 18, wherein:
the lower layer of insulating material defines a shallow trench isolation region that is adjacent to an active region of the semiconductor device structure; and
the gate structure is located over at least a portion of the active region.
